(19) United States
(12) Patent Application Publication
(10) Pub. No.: US 2007/0271931 A1
(43) Pub. Date: Nov. 29, 2007

(54) Method of Transformation of Heat and Work in Reversible Cycle Thermoelectrical Cycles Transformations and a Thermoelectric Transformer

(75) Inventor: Alexander Gorban, Kiev (UA)

Correspondence Address: KENYON & KENYON LLP, 1500 K STREET N.W., SUITE 700, WASHINGTON, DC, 20005, US

(73) Assignee: ELTHOM ENTERPRISES LIMITED, NICOSIA 1505 (CY)

(21) Appl. No.: 11/663,477

(22) PCT Filed: Sep. 29, 2004
(86) PCT No.: PCT/IB04/03164

§ 371 Date: May 1, 2007

(51) Int. Cl. H01L 35/30

(52) U.S. Cl. 62/3.2

(57) ABSTRACT

The Invention relates to a process for transforming heat and work in a thermoelectric cycle, wherein charge carriers of an electronic gas are cyclically subjected to at least a first and second (7) heat source. Thereby, heat is exchanged between elements of the cycle representing adjacent sections (c-d, d-a) of a thermodynamic representation of the thermoelectric cycle. The process can be performed without thermal loss and without thermal (entropy) degradation of the second source, which provides a thermoelectric efficiency higher than that of Carnot cycles.

### BACKGROUND OF THE INVENTION

1. Field of the Invention

The invention refers to electric phenomena including but not limited to the methods of generation and transformation of electric energy in thermoelectric processes and can be used in reversible cyclic thermoelectric transformations of heat into electric work and vice versa, for instance, in the process of electric energy at the expense of one of the two sources of heat of thermoelectric heating, cooling etc. in semiconductor structures, in which thermoelectric circular reversible transformations of the working substance in the form of the electronic gas are carried out.

2. Description of the Related Art

If the mechanical work of a thermodynamic process is a function of character of this thermodynamic process, the electric work of a thermoelectric process is the work of transport of an electric charge (or quantity of electricity) and carried out in an electric circuit. The work is equal to the product of the intensity of electric field, in which a charge is carried out (or the tension of charges of the electronic gas), and the quantity of electricity transported. Temperature and entropy, connected with electric charge carriers, have the same meaning as for a working substance in the form of molecular gas in a thermodynamic process. The work of the electronic gas is obtained through its thermal effects, through its electric effects, as well as through non-reversible processes of recombination of the charge carriers, i.e. recombination of electrons and holes, when excessive energy can be discharged in the form of quanta of electromagnetic radiation.

The method of thermoelectric transformation of heat into electric work of charge carriers is known, with circular cycle of the electronic gas, based on mutual relation of thermal and electric processes if an electric field and gradient of temperature simultaneously exist and on the transport of heat in the process of impact of the electronic flux on atoms of semiconductor with the electronic and hole conductivity. The method consists in the use of heat energy to carry out the work of transport of the electric current carriers (electrons and holes) in a closed circuit of thermocouple, in the direction opposite to electric fields.

The work of direct obtaining of electric energy is carried out at the expense of energy of heat sources of high and low temperature in reversible generalised thermoelectric cycles of transformation of heat of the two sources of high and low temperature, which contain two sections of isothermal processes with passage of some quantity of electricity through the contacts of thermocouple. Besides, that work is also carried out at the sections of two closing equidistant thermal processes, which are characterised by the change of quantity of electricity caused by movement of the current through semiconductor elements of thermocouples.

Since any known thermoelectric cycle can be presented as a sum of elementary Carnot cycles, the thermal efficiency of any known cycle cannot exceed that of the Carnot cycle. The Carnot cycle sets the limits of thermoelectric efficiency of any semiconductor thermotransformer, which works between the two given levels of temperatures of two heat sources.

In a direct cycle of transformation of heat into electric work, the maximum possible electric work at the output terminals of a thermoelectric generator is determined by the thermoelectric exergy of heat supplied, i.e. by the maximum work of the electronic gas from its initial state to anergic (unable to be transformed into work) state at the temperature of the environment. In the ideal direct reversible Carnot cycle, separation of the exergy of the heat supplied from the anergy contained in the heat. The exergy of the heat is abstracted in the form of useful electric work of the electronic gas, while the anergy of the heat is removed into the environment in the form of waste heat.

In the direct thermoelectric effect of T. Seebeck the thermal electric moving force (thermo-emf) in generated in the electric circuit, that consists of the couples of heterogeneous conductors or semiconductors, connected in series (with metallic cross-pieces). The junctions between those conductors or semiconductors are maintained at different temperatures. If the junction is heated, electrons migrate into the junction cooled, into a metal, from a n-type semiconductor, while holes migrate towards the cool junction through a p-type semiconductor. In this process, the heat is abstracted and the entropy of charge carriers increases. In this process, abstraction of heat and increase of the entropy of charge carriers takes place. Thermo-emf is proportional to the product of difference of temperatures on the junctions and the Seebeck coefficient, which depends on the temperature and density of charge carriers and physical properties of conductors and reaches its maximum for semiconductors with hole and the electronic conductivity.

If there is a difference in temperature along a conductor, i.e. in a warmer part of a conductor the mean energy of the current carriers becomes higher than in a cooler part, the effect of W. Thomson (Lord Kelvin) occurs: so called Thomson heat is discharged in a conductor with a current, characterised by the Thomson coefficient, uneven in relation to the current passing through the conductor and the temperature gradient. The Thomson coefficient changes its sign when the directions of the temperature gradient and the current change from the same to opposite.

The Peltier and Thomson effects set the total quantity of heat, abstracted through the junction into a semiconductor in the process of running of current through the junction.

In reverse processes, in the process of running of electric current through the junction of two different conductors, the thermoelectric effect of P. Peltier occurs: so called Peltier heat is discharged in thermojunctions, in addition to Joule heat if the direction of current is the same or the heat is abstracted if the direction of current is opposite. In contrast with the Joule heat that is proportional to the square of the intensity of current and is always discharged in conductors, the Peltier heat is proportional to the first degree of the intensity of current and the Peltier coefficient, which is a function of temperature. The sign of the Peltier heat depends on the direction of current in the junction. If the direction of current in a circuit is such that electrons, that possess lower energy, “abstract” heat from neighbouring atoms and transport it to another part of the circuit, one junction is cooled and another one is heated.

The method of thermoelectric transformation of electric work into heat in a reverse process, in the heating cycle of a heat pump, is known. The hot junction, maintained at the temperature higher that that of the environment, gives away to the heated volume the heat that contains the following two united components: exergy supplied as the necessary electric work and anergy abstracted as the heat from the environment. The quantity of heat discharged by the hot thermojunction exceeds that abstracted by the cold thermojunction. This difference is equal to the amount of energy used from the external source. This energy is used to carry out the work to maintain the current in the direction opposite to the direction of difference of electric potentials that emerge in a circuit if the temperature of the thermojunctions are different (according to the Seebeck effect) (Seebeck, T. J., 1822, Magnetische Polarisation der Metalle und Erze durch Temperaturdifferenz, Abhand. Deut. Akad. Wiss. Berlin, 265-373).

Also, the method is known of thermoelectric transformation of the electric work used in the reversed process, in the cooling cycle, if the necessary quantity of exergy is supplied to the cooling volume in the form of electric work, quantity of which is equal to the flow of anergy, which should be removed from the cooled volume and transferred to the environment in the thermoelectric cooling cycle the flow of charge carriers is accompanied with the heat flow, the electronic gas acts as a cooling agent that energy from the cooler to the hotter thermojunction (Peltier, J. C:, 1834, Nouvelles experiences sur la caloriecete des courans electriques. Ann. Chem.; LVI, 371-387.).

All known methods of transformation of heat and work based on conventional thermoelectric cycles have limited thermoelectric efficiency due to conceptually unavoidable thermal losses, which arise in the process of removing some part of heat of the working substance—the electronic gas, with the help of this process the decrease of entropy of heat supplying agent is compensated. In fact, due to the non-reversibility of the process, even in the most efficient thermotransformers, the useful work does not reach even one fifth of the maximum possible value because of large thermal loss.

The closest technical solution to the method proposed is the method of transformation of heat and work on the basis of thermoelectric cycles in semiconductor structures (Ioffe. A. F., 1957, Semiconductor Thermoelements and Thermoelectric Cooling, Infosearch, London). In the known direct cycle the heat from the heat supplying agent is entered into the cycle and partially converted into useful electric work in the exothermic process of increase of the entropy of charge carriers. After that the Thomson heat is given away and the isothermal process of decrease of the entropy of charges of the electronic gas at the temperature of the second source occurs, which cools the thermojunction of semiconductors with a metallic cross-piece, in the process of which the part of the heat in the form of thermal waste is given away out of the cycle into the heat abstractor (low temperature cycle), for instance, into the environment, where the degradation of thermal exergy of heat takes place, which is the main cause of decrease of the efficiency of the cycle. The part of the heat supplied to the cycle that is given away to the heat receiving agent, which compensates decreasing entropy of the heat supplying agent in the direct cycle, is proportional to the ratio of the temperature of the heat supplying agent and heat removing agent. In the process of reversible heat exchange the change of entropy of heat removing and supplying agents is equal and opposite in sign.

All known cycles have insufficient thermoelectric efficiency due to the fact that exergy waste is given away out of the system, which lowers their thermal and exergic efficiency.

Thus, there is a need for a method and/or processing system providing a more efficient solution of the problems described above. Particularly, it is desirable to provide a method of more efficiently transform heat and work in thermoelectric cycles.

### SUMMARY OF THE INVENTION

In accordance with the invention, as embodied and broadly described herein, methods and systems consistent with the principles of the invention provide for transforming heat and work in a thermoelectric cycle, wherein charge carriers of an electronic gas are cyclically subjected to at least a first and second heat source, characterized in that:

heat is exchanged between elements of the cycle representing adjacent sections of a thermodynamic representation of the thermoelectric cycle.

The term “electronic gas” therein broadly refers to electrons and “holes” provided by metals, or n-type of p-type semiconductors. The term “heat source broadly refers to sources and sinks of heat, irrespective of whether they are adiabatic or isotherm. The term “thermodynamic representation” broadly refers to all known thermodynamic diagrams, particularly to TS- and el-plots.

The method according to the invention and its embodiments is useful in solving the problems of enhancing the thermoelectric efficiency of the transformation of heat and work through modified thermoelectric cycles, which lay out of the limits of the Carnot cycle. This is achieved by changing the structure of heat exchange, compared to known cycles, in exergy saving (i.e. saving the exergy of energy carriers) and anergy closed (i.e. those without heat loss) regenerative reversible thermoelectric cycles, which satisfy the requirement of the first and second laws of thermodynamics, formularised by the generalised law of thermodynamics for systems with the working substance in the form of the electronic gas between the temperature levels of two heat sources, but without thermal loss and without thermal (entropy) degradation of the second source, which provides the thermoelectric efficiency higher than that of Carnot cycles.

In accordance with another aspect, the invention, as embodied and broadly described herein, methods and systems consistent with the principles of the invention provide a thermoelectric transformer according to claim 13.

Additional objects and advantages of the invention and its embodiments will be set forth in part in the description, or can be learned by practice of the invention. Objects and advantages will be realized and attained by means of the elements and combinations particularly pointed out in the appended claims. Embodiments of the invention are disclosed in the detailed description section and in the dependent and appended claims as well.

It is understood that both the foregoing general description and the following detailed description are exemplary and explanatory only and are not restrictive of the invention and its embodiments.

### BRIEF DESCRIPTION OF THE DRAWINGS

The accompanying drawings, which are incorporated in and constitute a part of this specification, illustrate examples of embodiments of the invention and, together with the description, explain the principles of the invention. In the drawings,

FIG. 1 shows for illustration purpose a block diagram of an electric circuit that describes the essence of the method of transformation of heat and work in thermoelectric exergy saving processes.

FIG. 2 shows for illustration purpose a diagram explaining the nature of thermodynamic transformation of heat into work. The thermodynamic diagram explains the essence of the method of transformation of heat into work in the thermoelectric direct exergy saving cycle a-b-c-d of the normal (direct) type (carried out clockwise), as a TS plot, where T is temperature, S is entropy.

FIG. 3 shows for illustration purpose an exergy diagram that explains the essence of the method of transformation of heat into work in the thermoelectric direct exergy saving cycle a-b-c-d of the normal type as an ei plot, where e is exergy, i is enthalpy.

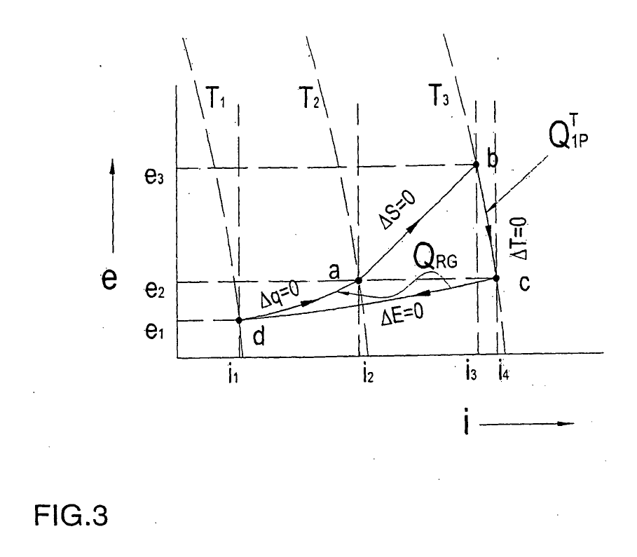

FIG. 4 shows for illustration purpose a heat diagram that explains the essence of the method of transformation of heat and work in the thermoelectric direct, reversible exergy saving cycle a-b-c-d of the abnormal type (carried out counterclockwise) as a TS plot, where T is temperature, S is entropy.

FIG. 5 shows for illustration purpose an exergy diagram that explains the essence of the method of transformation of heat into work in the thermoelectric direct exergy saving cycle a-b-c-d of the abnormal type as an ei plot, where e is exergy, i is enthalpy.

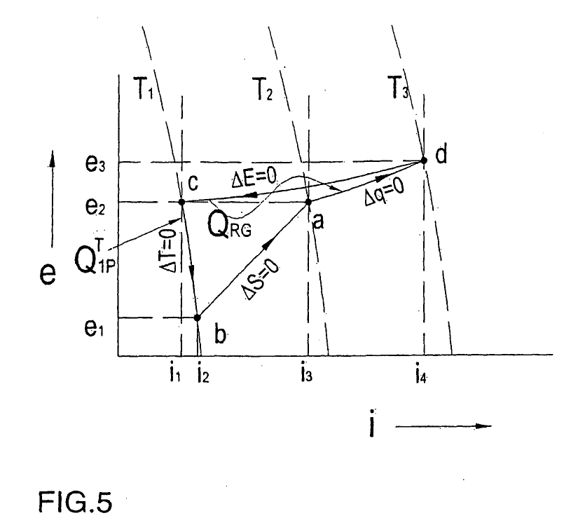

FIG. 6 shows for illustration purpose a heat diagram that explains the essence of the method of transformation of work into heat in the thermoelectric heating exergy saving cycle a-b-c-d of the normal type as a TS plot, where T is temperature, S is entropy.

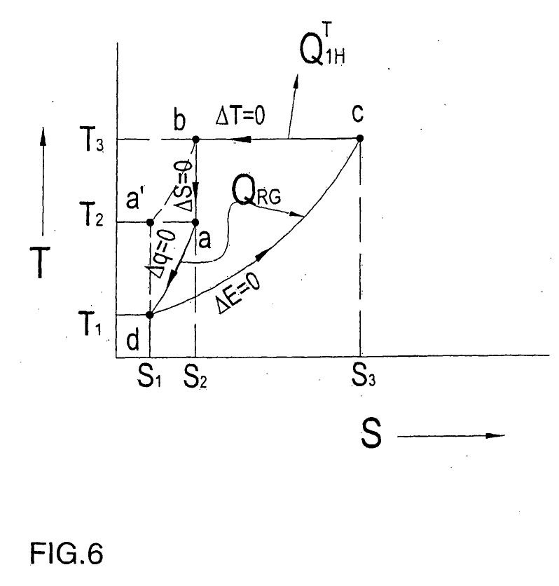

FIG. 7 shows for illustration purpose an exergy diagram that explains the essence of the method of transformation of work into heat in the thermoelectric heating exergy saving cycle a-b-c-d of the normal type as an ei plot, where e is exergy, i is enthalpy.

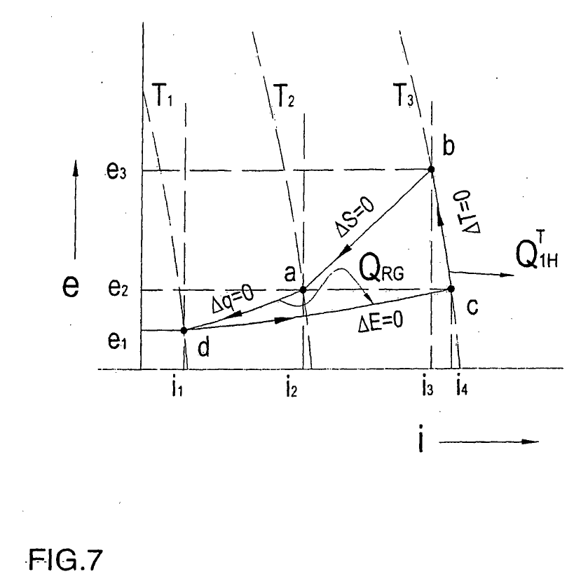

FIG. 8 shows for illustration purpose a heat diagram that explains the essence of the method of transformation of work into heat in the thermoelectric heating exergy saving cycle a-b-c-d of the abnormal type as a TS plot, where T is temperature, S is entropy.

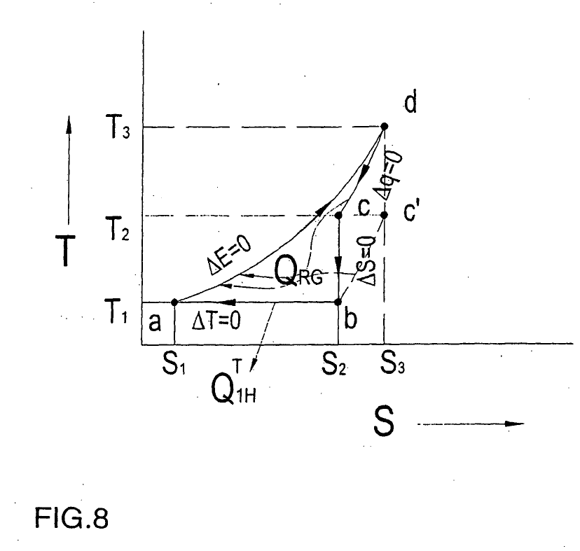

FIG. 9 shows for illustration purpose an exergy diagram that explains the essence of the method of transformation of work into heat in the thermoelectric heating exergy saving cycle a-b-c-d of the abnormal type as a ei plot, where e is exergy, i is enthalpy.

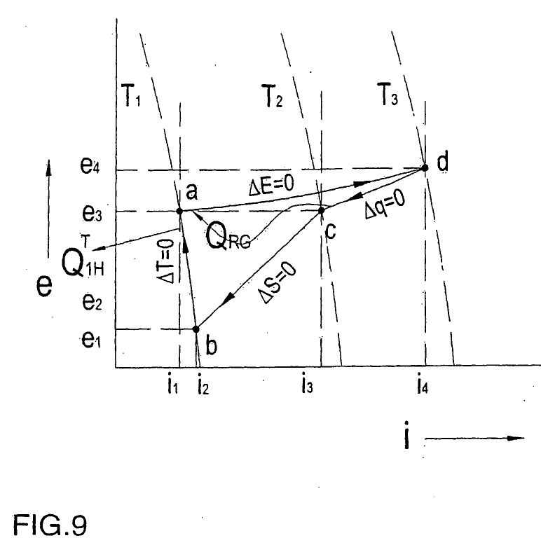

FIG. 10 shows for illustration purpose by means of a block diagram an example of a design of a direct exergy saving thermoelectric transformer that can be used to convert heat of the environment into electric energy and vice versa.

### DETAILED DESCRIPTION

Reference will now be made in detail to the principles of the invention by explaining the invention on the basis of an thermodynamic steam cycle process, examples of which are illustrated in the accompanying drawings. Examples, mentioned therein, are intended to explain the invention and not to limit the invention in any kind.

The method according to the invention and its embodiments may be carried out in methods of transformation of heat and work in thermoelectric processes, which may consist in reversible cyclic transformation of heat and work of charge carriers of the electronic gas in semiconductor structures. In the process of interaction of the electronic gas, at least, with two heat sources and heat exchange at the border of a thermoelectric system, an exchange of exergy of Peltier and Thomson heat, may be carried out at the border of the system between the limiting isentropes of the first heat source in periodic processes, which are formed from non-periodic complete transformations of heat and work of the electronic gas with circular transition of the electronic gas into its initial state through the second heat source with ideal regeneration of thermal exergy at different sections of non-reciprocal transitions of the electronic gas within the system and non-reversible increase of its entropy in the temperature field of the second source.

Thereby, ideal regeneration of the Thomson heat may be carried out with satisfying the balance of exergy of the electronic gas in the process of non-reciprocal transitions, while the changes of entropy of the first source can be compensated in the non-reversible process of permanent-cyclic change of the entropy of the working substance at the constant temperature and intensity (potential) of electric field without heat exchange with the second source and without electric work carried out by the electronic gas.

Accordingly, a preferred embodiment is characterized in that, the heat exchange is carried out at the sections of the cycle at constant value of potential and at constant value of charge of the electronic gas. The heat exchange can be a regenerative heat exchange of the thermal exergy of Thomson heat.

A further preferred embodiment is characterized in that the sections of heat exchange of the thermal exergy of Thomson heat within the cycle are closed by a section of isoexergic process of heat exchange. The sections of heat exchange can be sections of regenerative heat exchange of the thermal exergy of Thomson heat. The isoexergic process of heat exchange can be a polytropic process with constant thermal exergy of heat.

A further preferred embodiment is characterized in that the sections of heat exchange of the thermal exergy of Thomson heat within the cycle are closed by combinations of the sections with constant value of potential, with constant value of charge of the electronic gas, or with isothermal and isoentropic processes.

A further preferred embodiment comprises carrying out a direct cycle, wherein heat is supplied from the first heat source to the electronig gas, clockwise with respect to a thermodynamic representation, whereby the temperature of isothermal process of increase of the entropy of the electronic gas and abstraction of the heat of the first source by the electronic gas is set higher than the temperature of the state of thermal anergy of the electronic gas in the temperature field of the second source. The term “direct cycle” therein refers to a process of transforming heat into electric work.

Another embodiment comprises carrying out a direct cycle, wherein heat is supplied from the first heat source to the electronig gas, counterclockwise with respect to a thermodynamic representation, whereby the temperature of isothermal process of increase of the entropy of the electronic gas and abstraction of the heat of the first source by the electronic gas is set lower than the temperature of the state of thermal anergy of the electronic gas in the temperature field of the second source.

A further preferred embodiment comprises carrying out a reverse cycle counterclockwise with respect to a thermodynamic representation, wherein the temperature of isothermal process of transfer of the heat of the electronic gas to the heated environment and decrease of the entropy of the electronic gas is set higher than the temperature of the state of thermal anergy of the electronic gas in the temperature field of the first source. The term “reverse cycle” therein refers to a process of transforming electric work into heat.

A further preferred embodiment comprises carrying out a reverse cycle clockwise with respect to a thermodynamic representation, wherein the temperature of isothermal process of transfer of the heat of the electronic gas to the heated environment and decrease of the entropy of the electronic gas is set lower than the temperature of the state of thermal anergy of the electronic gas in the temperature field of the second source.

A further preferred embodiment is characterized in that the environment is used as the first heat source and a local adiabatic source of low temperature is used as the second source. Further, some part of electric work of the direct exergy saving cycle may be used for an additional cooling cycle, which may be carried out with isothermal process of heat abstraction in the temperature field of the second source.

A further preferred embodiment is characterized in that the environment is used as the first heat source and local adiabatic source of high temperature is used as the second source. Further, some part of electric work of the direct exergy saving cycle may be used for an additional heating cycle, which is carried out with isothermal process of discharging heat in the temperature field of the second source.

Besides, a non-reversible process of recombination of electrons and holes, in the form of quanta of electromagnetic radiation takes place.

A further preferred embodiment is characterized in that electric work is supplied and accumulated in an adiabatic system with consecutive removal and recuperation in the form of electric work.

A further preferred embodiment is characterized in that the scale of the heat's ability to work is established in accordance to the expression π_{T} lnπ_{P}, where π_{T} is the ratio of change of the temperature in the cycle, π_{P} is the ratio of change of the potential of the electronic gas in the cycle. For this change, heat is used from the first source of heat, supplied to the isothermal process of the electronic gas of the direct exergy saving cycle. The temperature of the working substance in the temperature field of the second source (in anergy state) is fixed. The exergy saving cycle may be carried out, the extents (ratios) of change of temperature and potential of the electronic gas may be measured and the heat's ability to work may be determined.

Subject of the invention is further a thermoelectric transformer for performing a method as described above, comprising at least one couple semiconductors with electronic and hole conductivity, metallic junctions, cooled and heated thermojunctions of semiconductors with metallic cross-pieces, characterized in that one semiconductor of the or each one couple is embodied in the form of a unit with constant potential of the electronic gas in the process of discharging of the Thomson heat, while the second of the or each one couple is embodied in the form of a unit with constant charge of the electronic gas in the process of the Thomson heat. Between both semiconductors, a heat exchanger is placed, preferably with ideal regeneration of thermal exergy of the Thomson heat with satisfying the balance of thermal exergy of the electronic gas in the process of its non-reciprocal transitions through semiconductors. The metallic cross-piece between them may be embodied in the form of the adiabatic system with a unit for compensation of entropy.

A preferred embodiment of the thermoelectric transformer is characterized in that the heat exchanger is embodied in the form of a heat tube or porous ceramics.

In a further preferred embodiment the thermoelectric transformer comprises a unit for compensation of entropy. The unit may be embodied in the form of a superconducting cross-piece in the adiabatic heat source or in the form of a unit that vacates non-reversibly some volume for accumulation of the electronic gas at the constant potential, temperature, enthalpy, without conducting work and consecutive releasing the electronic gas at constant charge.

In a further preferred embodiment of the thermoelectric transformer an additional thermoelectric transformer is connected to the thermotransformer. The additional thermotransformer may be placed into the thermotransformer with exergy saving cycle and adiabatic system of compensation of entropy, into the adiabatic source. The metallic cross-piece of this additional thermotransformer may be located in the adiabatic source. The additional thermotransformer may advantageaously be electrically connected with the main thermotransformer.

In a further preferred embodiment of the thermoelectric transformer an isentropic transformer of temperature of the electronic gas is connected in series with one of the semiconductors. The isentropic transformer may advantageaously be placed in the thermotransformer within the exergy saving cycle. It may be implemented, by way of non-limiting example, as in US patent application 2003/0072351 A1

Reference will now be made in more detail to the principles of the invention and its embodiments by an explanation on the basis of a thermoelectric process, examples of which are illustrated in the accompanying drawings. Examples, mentioned therein, are for explanatory purpose only and shall not to limit the invention in any kind.

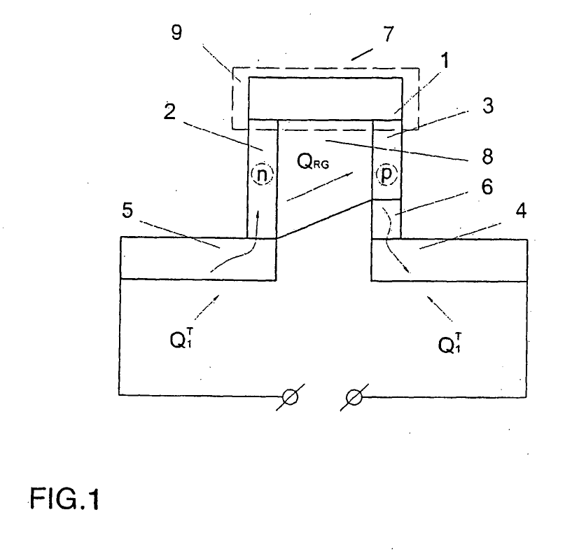

The proposed method of transformation of heat and work in thermoelectric exergy saving processes may be carried out in the following way: In FIG. 1 an electric circuit is shown, which consists of the metallic output contacts 4, 5 of at least a couple of different conductors and the semiconductors of n-type 2 and p-type 3, connected in series and separated by a conducting element (wire) 1, placed in the adiabatic accumulating heat source 7. The conductor 1 and adiabatic source 7 are used to compensate the entropy of the heat supplying agent. The metallic thermojunction of the contacts 4,5 with the semiconductors 2,3 and the thermojunctions of the conductor 1 have different temperatures, because the contacts 4,5 have the temperature T3 heat supplying agent, that is the source of high temperature (for instance, the environment), while the conductor 1 is located within the adiabatic shell 7 with the carrier of low temperature T1 (for instance, liquified nitrogen 9 for the normal direct cycle, carried out clockwise) or high temperature (for instance, the melt of a salt for the abnormal direct cycle, carried out counterclockwise). Between the conductor 4 and semiconductor 3, the isentropic transformer of temperature c [symbol] the electronic gas 6 is installed. Between the semiconductors 2 and 3 with the help of heat exchanger 8, conditions for ideal regeneration of the exergy of the Thomson heat with satisfying the balance of exergy of the electronic gas in the process of non-reciprocal transfer of the Thomson heat from the semiconductor 2 into the semiconductor 3 are established.

In the process of heating the thermojunction 4,6 and 2,5 electrons migrate towards the cooled junction 3,1 through the n-type semiconductor, while holes migrate towards the coo [symbol] junction 2,1 through the p-type semiconductor. In this process, the Peltier heat is abstracte [symbol] and the entropy of charge carriers is increased. On the contacts 4,5 thermo-emf is generated, which is proportional to the product of the difference of the temperature on the thermojunctions and the Seebeck coefficient.

The temperature difference along the semiconductor results in the larger mean energy of carriers of the current in the warmer part of the semiconductor 2 than that in the cooler pa [symbol] the Thomson heat is discharged in the semiconductor 2 with the current and the Thomson heat in the semiconductor 3 is abstracted. The Peltier and Thomson effects determine the total quantity of heat, taken away through the thermojunction into the semiconductor in the process of passing of the current.

When the electric current from an external source passes through the thermoelectric transformer, the Peltier heat is discharged on the thermojunctions. The hot thermojunction at the temperature higher than that of the environment, gives to the heated object the heat that consists of the following two components: the exergy, supplied in the form of the necessary electric work and anergy, abstracted in the form of heat from the environment [symbol] the cool junction. The quantity of heat, discharged by the warmer thermojunction, exceeds the quantity of heat, abstracted by the cooler thermojunction, by the value of electric energy from the external source being used. This energy is used to carry out the work of transport of carriers of the current in the direction opposite to the difference of electric potentials, th [symbol] originate in the circuit according to the Seebeck law if the temperature of the thermojunctions is different (Seebeck, T. J., 1822, Magnetische Polarisation der Metalle und Erze durch Temperaturdifferenz, Abhand. Deut. Akad. Wiss. Berlin, 265-373).

The first law of thermodynamics states the equivalence of heat and work, as the methods transformation of energy without any reservations. The second law does not ban the possibility of complete conversion of heat of one source into work if during these processe [symbol] some other changes are carried out as well. For instance, during non-periodic isothermal thermoelectric process of complete reversible transformation of heat into work of the electronic gas, the charge of the electronic gas changes.

In direct cyclic processes of conversion of heat into work, the heat of high temperature source should be supplied to the hot thermojunction (as the first law requires). Further, tha [symbol] heat should be abstracted from the cold thermojunction to the low temperature source (as the second law required), while the compensating generation of entropy takes place.

The second law of thermodynamics is applicable to thermoelectric effects, the electric energy has zero entropy, but the process of its converting into heat energy is non-reversible, because the process of increasing the entropy due to discharging the Joule he in conductors and cores takes place at the same time.

In the circular cycle of the electronic gas, if the electric circuit of thermocouple is closed al constant temperature difference is created and maintained, the three thermoelectric effect take place at the same time, while the relation between the Peltier, Thomson and Seebeck coefficients is set by the Kelvin relations. The work of the electronic gas in the circular cyc [symbol] performed by the thermo-emf if a given quantity of electric charge passes through, in accordance with the first law of thermodynamics, is determined by the difference of the quantities of heat supplied and heat abstracted.

The first and second laws of thermodynamics for isolated systems, that include all bodies undergoing any changes, are separated, because they are formulated in the form of reversible equality and non-reversible inequality, correspondingly. They can be unified into the generalised law of thermodynamics only by means of determining the conditions of complete reversible cyclic transformation of the heat of one source and work in the system of two heat sources, but without entropy degradation of the second source in the circular cycle.

The essence of the generalised law for thermoelectric circular reversible processes consist in stating the possibility and conditions of carrying out reversible complete cyclic transformation of heat of one source into work with the help of another source, but without entropy degradation of the second source in sample cycles.

For reversible thermoelectric transformation of heat and work of carriers of electric charge of the electronic gas in the circular cycles of the electronic gas, the heat of the one source and the work of carriers of electric charges of the electronic gas are equivalent as is shown by the methods of transformation of energy and completely reversible in circular processes that are formed from non-periodic complete transformations of heat and work of carriers of electric charges by means of circular transition of the electronic gas into the initial state through the second heat source with ideal regeneration of thermal exergy of non-reciprocate transformations and irreversible increasing of the entropy of the electronic gas at constant temperature and intensity of electric field without heat exchange and conducting work by the electronic gas.

In accordance to this, reversible exergy saving transformation of heat and work according to the method is carried out. Exergy saving (i.e. saving the exergy of energy carriers) or free from anergy loss (i.e. having no heat waste in ideal cycles) carrying out the cycles is accompanied by the special compensating change of the entropy of the high temperature heat source—heat supplying agent. Interaction of the three physical antipodes—entropy, exergy and anergy, in accordance with the generalised law, changes the structure of heal exchange in a radical way and cardinally enhances the efficiency of the method of reversible transformation of heat and work in regenerative thermoelectric cycles, carried O [symbol] between the temperature levels of two heat sources, with the working substance in the for of electronic gases, without transfer of a part of the exergy of the heat from the one heat source to the other and without entropy degradation of the other source.

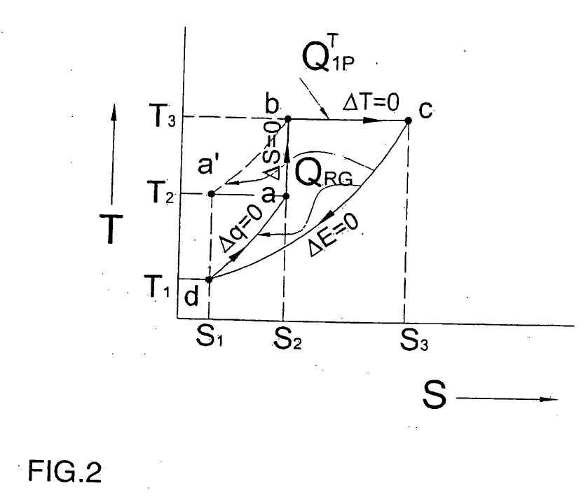

In FIG. 2 of the direct exergy saving thermoelectric cycle a-b-c-d of the normal type, transformation of heat into work in isothermal (ΔT=0) process a-b is shown as a TS-plot. I [symbol] this process, at the sections of isentropes S2 and S3 the heat QT1, that is equal to the su [symbol] of heat of Peltier and Thomson is abstracted by the thermojunctions 5,2 and 4,6 and completely transformed into thermoelectric exergy of the electronic gas. The entropy of the heat supplying agent—the source of high temperature T3 (for instance, the environment) decreases, the heat, that is equal to the sum of Peltier and Thomson heat, in isothermal process b-c is given to the thermojunctions 5,2 and 4,6. In this process, the exergy of the heat supplied is completely transformed into the work of electric charge carriers, which is accompanied by increase of charge and increase of intensity of electric field. In thermal interactions, the entropy transferred through the limits of the system is exchanged. Therefore, if the entropy of heat supplying agent decreases, the entropy of the electronic gas and its charge increase. The changes in entropy at the sections of heat exchange with heat supplying agent are equal and opposite in sign.

The return into the initial state is carried out with complete ideal regeneration of the thermal exergy of the Thomson heat ORG in non-reciprocal transitions 2-8-3 (in FIG. 1), c-d (in FIG. 2) and 3-8-2 (in FIG. 1), d-a or a′-b (in FIG. 2), with satisfying the exergy balance. The thermal exergy of the electronic gas in the form of Thomson heat ORG regenerates within the cycle in the non-reciprocal way, i.e. at opposite (unlike) sections 2-8-3 (in FIG. 1), portion c-d (in diagram of FIG. 2) and 3-8-2 (in FIG. 1), portion d-a or a′-b (in diagram of FIG. 2). In the process of circulations, prior to crossing the limits of the adiabatic shell 7 of the second source, the thermal exergy of the electronic gas in the form of the Thomson heat QRG is separated from the electronic gas itself and supplied to the semiconductor 3, through the heat exchanger 8, embodied, for instance, as heat tubes. The temperature of heat supplying agent—that of the Thomson heat—decreases along the semiconductor 2 up to the temperature of the carrier of low temperature T1 at the constant potential (intensity of electric field) and decrease of charge in the process of giving away of the Thomson heat at the section 2-8-3 (in FIG. 1), portion c-d (in FIG. 2).

The thermal exergy of the Thomson heat QRG of the electronic gas, abstracted from the isopotential or isotonic section (with constant intensity, ΔE=0) section c-d, with decreasing the temperature from T3 to T1, should be equal to the thermal exergy of the Thomson heat at the isopycnic (with constant density of charge, Δq=0) section d-a, needed to increase the temperature of the electronic gas from T1 to T2.

It can be shown that if the following condition is satisfied:

$$\frac{{T}_{3}}{{T}_{1}} - ln \frac{{T}_{3}}{{T}_{1}} = \frac{{T}_{2}}{{T}_{1}} - k ln \frac{{T}_{2}}{{T}_{1}} or {π}_{T ( Δ E = 0 )} - ln {π}_{T ( Δ E = 0 )} = {π}_{T ( Δ q = 0 )} - k ln {π}_{T ( Δ q = 0 )}$$

where k is the coefficient determined by the characteristics of semiconductors;

π_{T(ΔE=0)}, π_{T(Δq=0)} is the extent (ratio) of change of temperature in isothonic and isopycnic processes, correspondingly.

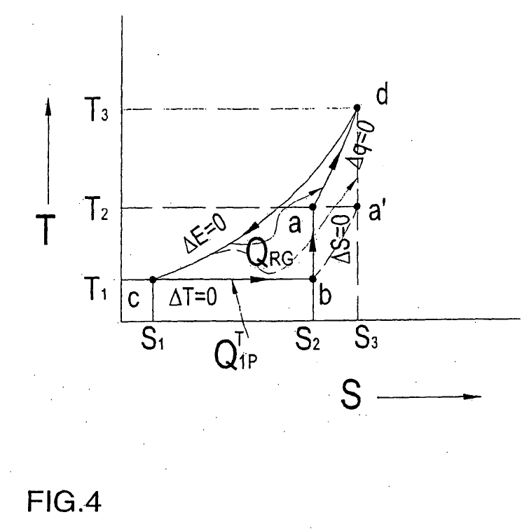

The formulae enable us to calculate T₂ on the basis of the known values T₁ and T₃ in the process of regeneration at the neighbouring sections of the normal direct exergy saving cycle a-b-c-d shown in FIG. 2 and in the process of regeneration at the opposite sections of the abnormal direct exergy saving cycle a′-b-c-d shown in FIG. 4.

In known direct (not generalised) Carnot cycles, between the two limiting isentropes of heat, both conversion of heat into work (the main process) and return into the initial state (auxiliary, compensating process) take place, with heat removing to a cooler. In exergy saving cycles, between the two limiting isentrope lines of heat S2, S3 only the main process of abstracting the heat supplied and changing charge carriers takes place, while the auxiliary process of the return into the initial state is carried out with the transfer to the isentrope line S1 (in the normal cycle a-b-c-d, FIG. 2 with regeneration of the Thomson heat at the neighbouring sections of the cycle or a′-b-c-d, FIG. 4 with regeneration at the opposite sections) or S3 (in the abnormal cycle, 1-2-5-6 with regeneration of the Thomson heat at the opposite sections of the cycle or 1-2-5′-6 with regeneration at the neighbouring sections), located out of the limiting isentropes of the heat transformed, under the conditions of the temperature field of the second source 7 of low (in the normal cycle) or high (in the abnormal cycle) temperature, being closed for exergy of the electronic gas. Passage of the electronic gas through the second source 7 is carried out in the state of thermal anergy, without heat exchange with it and without conducting work.

The compensating entropic process is carried out by the system 1, e.g. a cross-piece or cross-strap, of compensation of entropy by means of volumetric change of the anergy of the electronic gas without conducting work. The anergy flow of the electronic gas is directed into the system 1 to carry out the entropic compensating process. After passing the system 1 and completing the process of compensation of the entropy of the heat supplying agent, the electronic gas, in the process of passing through the semiconductor 3, completely absorbs the supplied thermal exergy of Thomson heat and enhances its temperature and entropy, at the expense of Thomson heat due to the thermal contact of charge carriers of the electronic gas with the same parts of the regenerator in reverse order, but in non-reciprocal way, for instance, under the conditions of constant charge, to a lower temperature and entropy because of the difference of the coefficients of Seebeck for the materials of p- and n-types at the constant intensity of the field and constant charge. Regenerative processes are carried out with satisfying the exergy balance, i.e. ideally, without exergy loss, can be completely reversible and completely independent on sources.

The heat of the environment is supplied to the contact plates 4,5 at the temperature of the environment on the hot thermojunction. The cold thermojunctions 2,1 and 3,1 may, for example, be maintained at the temperature of liquified nitrogen of the source 7. When the electric circuit of the generator is being closed and the electric current is passing through, the following three thermoelectric effects are originating: Seebeck's, Peltier's, Thomson's and the effect of superconductivity in the cryogenic junction 1 at the temperature of liquified nitrogen may be established by choosing the appropriate materials for cross-piece 1. When the heat of the environment is supplied to the metallic contact plates 5,4 and the super-conducting cross-piece 1 of p-n junction is cooled, thermo-emf is originated on the couples of semiconductors (the effect of Seebeck). The Thomson heat is exchanged between the semiconductors 2,3 through the regenerative heat exchanger 8 takes place with satisfying the exergy balance in such a way that at the same temperatures in the field of temperature gradients of each semiconductor the value of the entropy of charge carriers (electrons and holes) at the sections of the return into the initial state are different. This is achieved by means of choosing the suitable values of thermo-emf coefficient of the semiconductors 2,3 and different conditions of the regenerative processes—under the conditions of constant intensity of electric field and constant quantity of electricity. Some part of the work may be used in the process of the return into the initial state at the section a-b to enhance the electric potential up to the initial state by the unit 6 of adiabatic increase of temperature of the electronic gas from T2 to T3 (FIG. 2).

Passage of the current through the superconducting cross-piece 1 in the adiabatic source 7 is not accompanied by dissipation of electrons, discharge of heat and entropy degradation of the accumulating cryogenic 9 source 7. That degradation takes place as result of abstraction by the thermal accumulator 7 of the heat transferred from the hot end of semiconductors to the cold one as a result of their heat conduction if there is a temperature gradient on the ends of the semiconductors 2,3. Besides, heat penetrates into the source 7 because of non-perfect thermal isolation of the adiabatic shell 7.

What kind of changes may be being carried out in the thermotransformer and its electronic gas in the circular cycle? These are determined by the law of conservation of entropy in reversible circular processes. After the reversible cycle is implemented, the transformer returns into the initial state without any consequences. The reversible process in this case is equivalent to the absence of the process. Therefore the entropy of a cyclic machine and its electronic gas throughout the cycle remain unchanged, which is equivalent of the absence of any changes in the machine.

Since the law of conservation of entropy in reversible circular processes mentioned above is also applicable to the entire system, considered as a whole, taking into account all the bodies, the entropy should be enhanced in order to close the entropy balance of the system. The compensating process of non-reversible change of entropy in exergy saving thermoelectric cycles is carried out not through giving away the heat of the electronic gas to heat receiving agent, like in Carnot cycles, but rather by means of changing the anergy, originated after converting the thermal exergy of the electronic gas into the anergy through removal of the Thomson heat. In the process of abstracting of the Thomson heat from electronic gas and its passage into the volume being vacated in the system of compensation 1 in the temperature field of the adiabatic source the change in charge and non-reversible entropic change of volumetric, potential anergy and the entropy of the electronic gas at the constant temperature and intensity of electric field, without conducting work, in non-reversible continuous-cyclic process, take place.

The compensating generation of entropy is carried out at the expense of the loss of the work which otherwise would has been conducted in the process of transition of the working substance to a more stable state in diffusion, freezing, condensation, explosion or recombination, in the non-reversible process of expansion to release some volume for charge carriers at constant intensity of the electric field and temperature, etc.

The following two kinds of carriers are used as charge carriers: electrons and holes. The increase of the entropy is carried out in this case at the expense of the loss of work. This increase of the entropy is an analogue of the entropy change in the Gibbs' paradox: in the process of mixing two gases, after removal of the partition between their geometric volumes, the internal energy, enthalpy, temperature and pressure are not changing, but the entropy of the mixture is increasing more than the additive sum of entropies of the mixing gases.

The entropic process in this case is not accompanied with giving away the heat to the second source in the form of anergy, the part of the energy of the electronic gas that is unable to work, or exergy, the part of the energy of the electronic gas that is able to work. The valuable exergy of heat is completely used within the cycle, which makes it more effective than the Carnot cycle for the electronic gas.

Within the framework of this method, the functions of the two heat sources as well as the structure of heat exchange in exergy saving cycles are conceptually different from those of the Carnot cycles: the working source exchanges heat with the electronic gas, while the second source (the adiabatic source) may be closed for such an exchange. With the use of the second source the volumetric change of the charge of the electronic gas in the state of thermal anergy and transformation of entropy may be carried out. The thermal potential of the adiabatic source is useful to change the thermal state of thermal state of the electronic gas outside the adiabatic source, in the process of circulation of the electronic gas in the cycle. The exergy of the adiabatic source is not used in the exergy saving cycles (similarly, the energy of constant magnets is not used in magneto-electric effects).

Some new phenomena are being revealed: in any thermoelectric exergy saving cycle with the electronic gas, heat flows from the cycle into the heat absorber are absent, the temperature of an adiabatic source can be set either below or above the corresponding parameters of the working source, for instance, the environment. The thermodynamic cycles can have either normal (conventional) sequence (passage) of thermal processes, i.e. the clockwise direction for direct cycles, the counter-clockwise direction for reverse (cooling and heating cycles) or abnormal sequence, i.e. the counter-clockwise direction for direct cycles, the clockwise direction for cooling and heating cycles.

The passage of the electronic gas in the state of thermal anergy through the adiabatic source without heat exchange with it, under the conditions of constant temperature, does not result in degradation of the heat energy of the adiabatic source. Degradation of local adiabatic sources occurs only because of non-ideal thermal isolation of a local source, for instance, an accumulating heat carrier in a Dewar flask and technical dissipation of heat by parts of the system; in particular, due to thermal conductivity of semiconductors, if there is a temperature difference, heat is transferred from the hot thermojunction to the cold one.

The sections of regenerative heat exchange of thermal exergy of the Thomson heat in the cycle (portions c-d and d-a or a′-b in diagram of FIG. 2) can be closed by the single section of isoexergic process of heat exchange—the polytropic process of supplying or abstracting of heat under the conditions of constant thermal exergy of the heat or combinations of the sections with constant value of potential, with constant value of charge of the electronic gas, or with isothermal (portion b-c in diagram of FIG. 2) and isentropic processes (portion a-b or a′-d in diagram of FIG. 2).

In a process of carrying out the direct cycle clockwise, the temperature of isothermal process of increasing the entropy of the electronic gas and abstraction of the heat of the first source by the electronic gas may be set higher than the temperature of the state of thermal anergy of the electronic gas in the temperature field of the second source.

In a process of carrying out the direct cycle counterclockwise the temperature of isothermal process of increasing the entropy of the electronic gas and abstraction of the heat of the first source may be set lower than the temperature of the state of thermal anergy of the electronic gas in the temperature field of the second source.

In a process of conversion of the direct cycle by means of applying some electric work to carry out the reverse heating cycle counterclockwise, the temperature of isothermal process of giving away the heat of the electronic gas to the heated environment and decreasing the entropy of the electronic gas, may be set higher than the temperature of the state of thermal anergy of the electronic gas in the temperature field of the first source.

In a process of conversion of the direct cycle by means of applying some electric work to carry out the reverse heating cycle clockwise, the temperature of isothermal process of giving away the heat of the electronic gas to the heated environment and decreasing the entropy of the electronic gas, may be set lower than the temperature of the state of thermal anergy of the electronic gas in the temperature field of the first source.

The environment may be used as the first heat source heat and a local adiabatic source of high temperature may be used as the second source, some part of electric work of the direct exergy saving cycle of the abnormal type may be used and the additional heating cycle with isothermal process of discharging heat in the temperature field of the second source may be carried out.

In the exergy saving cycles the non-reversible processes of recombination of electrons and holes, in the form of quanta of electromagnetic radiation, are carried out.

Electric work may be supplied and accumulated in the exergy saving cycles, in the adiabatic system with consecutive abstraction and recuperation in the form of electric work. The scale of the heat's ability to work may be established in accordance to the expression Π_{T} ln Π_{P}, where Π_{T} is the extent (ratio) of change of the temperature in the exergy saving cycle, Π_{P} is the extent (ratio) of change of the potential of the electronic gas in the cycle, for which heat is used as the first source of heat, supplied to the isothermal process of the electronic gas of the direct exergy saving cycle, for which the temperature of thermal anergy of the working substance in the temperature field of the second source is fixed, the exergy saving cycle is carried out, the extents (ratios) of change of temperature and potential of the electronic gas are measured and the heat's ability to work is determined. With the help of semiconductor thermal transformations, by means of simultaneous use of the thermoelectric effects described above, it may be created new thermoelectric sources of electric current, thermoelectric sources of heat of high or low temperature or thermoelectric sources of electromagnetic radiation (quantum sources of light or UHF generators), that use the heat energy of the environment as their source of energy.

The Thermoelectric Transformer

Thermoelectric transformers are known for direct transformation of the temperature difference of two heat sources into electric potential and reverse transformation of electric work into the heat, supplied to the heated environment or abstracted from the cooled object (Seebeck, T. J., 1822, Magnetische Polarisation der Metalle und Erze durch Temperaturdifferenz, Abhand. Deut. Akad. Wiss. Berlin, 265-373; Peltier, J. C:, 1834, Nouvelles experiences sur la caloriecete des courans electriques. Ann. Chem.; LVI, 371-387; Thomson, W., 1851, On a mechanical theory of thermoelectric currents, Proc. Roy. Soc. Edinburgh, 91-98).

The closest technical solution according to the state of the art to the proposed thermoelectric transformer is a semiconductor thermotransformer for generating electricity, heating or cooling (U.S. Pat. No. 6,384,312), that comprises at least one couple of semiconductors with electronic and hole conductivity and a metallic cross-pieces electrically connecting the or each couple (cooled and heated thermojunctions of semiconductors with metallic junctions).

Known thermotransformers have insufficient efficiency of thermoelectric transformation because of incomplete use of heat and electric energy and dumping of thermal waste from the system, which lowers their thermal and exergy efficiency.

The problem to be solved by the thermoelectric transformer according invention and its embodiments is enhancing of thermoelectric efficiency of thermotransformers of heat and work.

The problem is solved by means of a thermotransformer, which contains, at least, a couple of semiconductors with electronic and hole conductivity and metallic cross-pieces, thermojunctions of semiconductors with metallic junctions, whereby one semiconductor transformer is embodied in the form of a unit with constant potential of the electronic gas in the process of discharging the Thomson heat, whereby the other is embodied in the form of the unit with constant charge of the electronic gas in the process of abstracting the Thomson heat. A heat exchanger with ideal regeneration of the Thomson heat is placed between them for satisfying the balance of thermal exergy of the electronic gas in the process of their non-reciprocal transitions through semiconductors. A metallic junction between them (cross-piece) may be embodied in the form of an adiabatic system with a unit for the compensation of entropy.

In a preferred embodiment, the heat exchanger with ideal regeneration of thermal exergy heat Thomson may be embodied as a heat tube or porous ceramics.

In a further preferred embodiment, the unit to for entropy compensation may be embodied as a unit for non-reversible vacating some volume to accumulate the electronic gas at constant potential, temperature, enthalpy without conducting work and consecutive giving away at constant charge.

In a further preferred embodiment, the unit for compensation of the entropy can be embodied in the form of the superconducting cross-piece in the adiabatic thermal accumulator.

In a further preferred embodiment, an additional thermotransformer may be placed in the thermotransformer within exergy saving cycle and adiabatic system of compensation of entropy, into the adiabatic source. The metallic cross-piece or cross-strap of this additional thermotransformer may be located in the adiabatic source. The additional thermotransformer may be electrically connected with the main thermotransformer.

In a further preferred embodiment an isentropic transformer of temperature of the electronic gas may be connected in series with semiconductors into the thermotransformer within the exergy saving cycle.

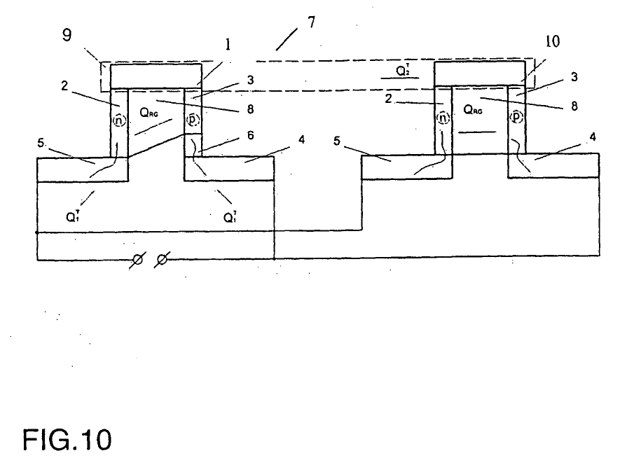

In FIG. 10, a non-limiting example of a version of a design of a direct exergy saving thermoelectric transformer, that converts heat of the environment into electric energy, is shown. It comprises the main thermoelectric generator of electric current 1,2,3,4,5,6,7,8,9 with the adiabatic autonomous source in the form of accumulating cryogenic source 9 in the adiabatic shell 7 and the built-in auxiliary reversed transformer 10,2,3,4,5,7,8,9, electrically connected with the main heat generator. The auxiliary cooling contour is used for compensation of entropic degradation of the adiabatic source 9 caused by non-ideal thermal isolation of the adiabatic shell 7 and non-reversible processes of thermal conductivity of the semiconductors 2,3.

The thermoelectric transformer contains at least one or a set of couples of semiconductors with electronic 2 or hole 3 conductivity, connected in series or cascade, the system of compensation of entropy 1, embodied, for instance, in the form of a cross-piece, that becomes superconducting at the temperature of the carrier 9 of the accumulating source, for instance, liquified nitrogen (78 K) in the adiabatic shell 7, metallic contact plates 4,5 for supplying the heat of the environment, which may also be used as conducting output terminals of the thermo-emf generator. Thermal contact for the Thomson heat may be provided between outer surfaces of the semiconductors 2,3 by means of thermal tubes of the heat exchanger-regenerator 8.

The heat of the environment may be supplied to the contact plates 4,5 at the temperature of the environment on the hot thermojunction. The cold thermojunction may be maintained at the temperature of liquefied nitrogen. When the electric circuit of the generator is being closed and the electric current is passing through, the following three thermoelectric effects are originating: Seebeck's, Peltier's, Thomson's and the effect of superconductivity in the cryogenic junction 1 at the temperature of liquefied nitrogen. When the heat of the environment is supplied to the metallic contact plates and the super-conducting cross-piece of p-n junction is cooled, thermo-emf is originated on the couples of semiconductors (the effect of Seebeck). The Thomson heat is exchanged between the semiconductors 2, 3 through the regenerative heat exchanger 8. The exchange takes place with satisfying the exergy balance in such a way that at the same temperatures in the field of temperature gradients of each semiconductor, the values of the entropy of charge carriers (electrons and holes) at the sections of the return into the initial state are different. This is achieved by means of choosing suitable values of thermo-emf coefficient of the semiconductors 2,3 and different conditions of the regenerative processes, e.g. conditions of constant intensity of electric field and constant quantity of electricity. Some part of the work may be used in the process of the return into the initial state to enhance the electric potential up to the initial state by the unit 6 of adiabatic increase of temperature of the electronic gas (FIG. 2).

Passage of the current through the superconducting cross-piece 1 in the adiabatic source 7 is not accompanied by dissipation of electrons, discharge of heat and entropy degradation of the accumulating cryogenic source 9. That degradation takes place as result of transport of heat into the thermal accumulator 7 from the hot end of semiconductors to the cold one as a result of their heat conduction if there is a temperature gradient on the ends of the semiconductors 2,3. Besides, heat penetrates into the source 9 because of non-perfect thermal isolation of the adiabatic shell 7.

If these conditions are satisfied, the heat of the environment acquire the ability to work on the electronic gas, while the cycle becomes exergy saving, i.e. the exergy of the electronic gas is completely used in the cycle. The compensating entropic process is carried out in the process of passage of electrons in the state of anergy through the superconducting cross-piece, when entropic change of volumetric, potential anergy of charge carriers occurs at constant temperature, without conducting work, in the non-reversible process.

This increase of the entropy takes place at the expense of loss of the work, which could have been carried out by electrons in the non-reversible process of transition into the more stable state of superconductivity of superfluid collective of electrons in the process of increase of the number of charge carriers with vacating some space for the electronic gas at constant temperature.

The efficiency of the direct exergy saving thermoelectric cycle is higher than that of thermoelectric transformation of heat into work by the electronic gas according to the Carnot cycle, therefore the exergy saving heat generator can be used with a continuously working contour of compensation of entropic degradation of cryogenic source—the thermoelectric cooling transformer 10,2,3,4,5,7,8,9, which works in accordance with the conventional cooling thermoelectric cycle of removal of the heat, that penetrates into the cryogenic source 9.

In the exergy saving heat generator (which at the same time is the thermoelectric cryogenic cooler with compensation of entropic degradation of cryogenic source), the exergy saving heat generator may be used as a source of current for regenerative transformer 10,2,3,4,5,7,8,9, which abstracts the heat, that penetrates into the cryogenic source. It contains the same elements, as the heat generator. However, the cryogenic junction 10 in it may be embodied from ordinary metal. It works on the basis of Peltier effect, so that the metallic cryogenic junction 10 absorbs the heat, while the hot thermojunctions discharge the quantity of heat, that exceeds the quantity of heat, abstracted by the cold cryogenic thermojunctions by the value of the energy of the heat generator, used to carry out the work of transport of charge carriers in the direction opposite to the electric fields. The heat of Peltier, Joule and the heat the environment are accumulated in the common heat accumulating plate and used by the heat generator.

The exergy saving thermoelectric transformer described above can be used as a source of current for electric power supply for communication, computers and provide simultaneous cryogenic cooling of microelectronic components, for instance, computer processors, UHF elements, etc with the use of the heat energy of the environment and with the help of the second heat source, but without its entropic degradation.

Besides, the technical possibilities can be shown of carrying out abnormal thermoelectric cycles, the possibilities of creation of heat pumps for maintaining a required air temperature in a closed volume and carrying out heating exergy saving cycles with the help of thermoelectric heating machines, thermoelectric quantum sources of light, etc. that use the heat energy of the environment.

Modifications and adaptations of the present invention will be apparent to those skilled in the art from consideration of the specification and practice of the invention disclosed herein. The foregoing description of an implementation of the invention has been presented for purposes of illustration and description. It is not exhaustive and does not limit the invention to the precise form disclosed. Modifications and variations are possible in light of the above teachings or can be acquired from the practicing of the invention. It is intended that the specification and examples be considered as exemplary only, with a true scope and spirit of the invention being indicated by the following claims.

1. A method for transforming heat and work in a thermoelectric cycle, wherein charge carriers of an electronic gas are cyclically subjected to at least a first and second heat source, and wherein heat is exchanged between elements of the cycle representing adjacent sections of a thermodynamic representation of the thermoelectric cycle.

2. A method according to claim 1, wherein the heat exchange is carried out at the sections of the cycle at constant value of potential and at constant value of charge of the electronic gas.

3. A method according to claim 1, wherein the sections of heat exchange of the thermal exergy of Thomson heat within the cycle are closed by a section of isoexergic process of heat exchange.

4. A method according to claim 1, wherein the sections of heat exchange of the thermal exergy of Thomson heat within the cycle are closed by combinations of the sections with constant value of potential, with constant value of charge of the electronic gas, or with isothermal and isoentropic processes.

5. A method according to claim 1, further comprising:
carrying out a direct cycle, wherein heat is supplied from the first heat source to the electronig gas, clockwise with respect to a thermodynamic representation, whereby the temperature of isothermal process of increase of the entropy of the electronic gas and abstraction of the heat of the first source by the electronic gas is set higher than the temperature of the state of thermal anergy of the electronic gas in the temperature field of the second source.

6. A method according to claim 1, further comprising:
carrying out a direct cycle, wherein heat is supplied from the first heat source to the electronig gas, counterclockwise with respect to a thermodynamic representation, whereby the temperature of isothermal process of increase of the entropy of the electronic gas and abstraction of the heat of the first source by the electronic gas is set lower than the temperature of the state of thermal anergy of the electronic gas in the temperature field of the second source.

7. A method according to claim 1, further comprising:
carrying out a reverse cycle counterclockwise with respect to a thermodynamic representation, wherein the temperature of isothermal process of transfer of the heat of the electronic gas to the heated environment and decrease of the entropy of the electronic gas is set higher than the temperature of the state of thermal anergy of the electronic gas in the temperature field of the first source.

8. A method according to claim 1, further comprising:
carrying out a reverse cycle clockwise with respect to a thermodynamic representation, wherein the temperature of isothermal process of transfer of the heat of the electronic gas to the heated environment and decrease of the entropy of the electronic gas is set lower than the temperature of the state of thermal anergy of the electronic gas in the temperature field of the second source.

9. A method according to claim 1, wherein the environment is used as the first heat source and a local adiabatic source of low temperature is used as the second source.

10. A method according to claim 9, wherein the environment is used as the first heat source and local adiabatic source of high temperature is used as the second source.

11. A method according to claim 1, wherein electric work is supplied and accumulated in an adiabatic system with consecutive removal and recuperation in the form of electric work.

12. A method according to claim 1 wherein the scale of the heat's ability to work is established in accordance to the expression π_{T} ln π_{P}, where π_{T} is the ratio of change of the temperature in the cycle, π_{P} is the ratio of change of the potential of the electronic gas in the cycle.

13. A thermoelectric transformer for performing a method of claim 1 comprising at least one couple semiconductors with electronic and hole conductivity, metallic junctions, cooled and heated thermojunctions of semiconductors with metallic pieces electrically connected to the semiconductors, wherein:
one semiconductor of the at least one couple is embodied in the form of a unit with constant potential of the electronic gas, and
the other semiconductor of the at least one couple is embodied in the form of a unit with constant charge of the electronic gas and and
both semiconductors of the at least one couple are connected by a heat exchanger.

14. A thermoelectric transformer according to claim 13, wherein the heat exchanger is embodied in the form of a heat tube or porous ceramics.

15. A thermoelectric transformer according to claim 13, further comprising:
a unit for compensation of entropy.

16. A thermoelectric transformer according to claim 13, wherein an additional thermoelectric transformer is connected to the thermotransformer.

17. A thermoelectric transformer according to claim 13 wherein an isentropic transformer of temperature of the electronic gas is connected in series with one of the semiconductors.

18. A thermoelectric transformer according to claim 13 wherein a unit for recombination of electrons and holes is connected in series with one of the semiconductors.
